(19) United States
(12) Patent Application Publication
(10) Pub. No.: US 2006/0201693 A1
(43) Pub. Date: Sep. 14, 2006

(54) COVER MECHANISM FOR DATA STORAGE DEVICE

(76) Inventor: Yang-Ming Lin, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,487

(22) Filed: Dec. 29, 2005

(30) Foreign Application Priority Data
Mar. 11, 2005 (CN) 2005100336210

(51) Int. Cl. H05K 5/03

(52) U.S. Cl. 174/66

(57) ABSTRACT

A cover mechanism for protecting a storage device (7) includes a bezel (3), a cover (1), a resilient member (2), and a pair of relay members (4). The bezel defines an opening (31) for the storage device passing therethrough, and a pair of passages (36) for slidably holding the relay members therein. The cover includes a pair of connecting tabs (15) each defining a pivoting hole (151). Each of the relay members includes a shaft (41) pivotably received in a pivoting hole, and a body (43) sliding in a passage. Two ends of the resilient member are separately fixed to the cover and the bezel.

### FIELD OF THE INVENTION

The present invention relates to cover mechanisms, and particularly to a cover mechanism which can protect a data storage device from contamination and humidity.

### DESCRIPTION OF RELATED ART

Data storage devices, such as optical disk drives, are installed in a computer enclosure for communication and processing data. An optical disk drive includes a case and a tray received in the case. The tray can accommodate an optical disk therein, and read data from the optical disk. A front bezel is positioned in front of the optical disk drive. An opening is defined in the front bezel. The tray can be moved into or out of the case through the opening of the front bezel.

For example, a typical personal computer includes an enclosure for protection of internal devices, such as hard disk drives, compact disk read-only memory (CD-ROM) drives, motherboard, and the like. To access the CD-ROM drive, an opening is defined in the enclosure. However, contamination and humidity often harm the personal computer via the opening.

To address aforementioned problem, an enclosure having a protective cover as described in China Patent No. 98220678.X is invented. The enclosure includes a front panel defining an opening, and a cover is pivotably attached to the front panel via pivots for shielding the opening. However, the cover includes a protruding part which always extends out of a front bezel no matter the cover is open or closed so that the cover is prone to be damaged in transportation or in use due to any accidental impact. This contingency usually leads to a short life and an unpleasant appearance of the cover.

What is desired, therefore, is a cover mechanism protecting a data storage device from any accidental damage.

### SUMMARY OF INVENTION

In one preferred embodiment, a cover mechanism for protecting a storage device includes a bezel, a cover, a resilient member, and a pair of relay members. The bezel defines an opening for the storage device passing therethrough, and a pair of passages for slidably holding the relay members therein. The cover includes a pair of connecting tabs each defining a pivoting hole. Each of the relay members includes a shaft pivotably received in one of the pivoting holes, and a body sliding in one of the passages. Two ends of the resilient member are separately fixed to the cover and the bezel.

Other advantages and novel features will become more apparent from the following detailed description of preferred embodiments when taken in conjunction with the accompanying drawings, in which:

### BRIEF DESCRIPTION OF DRAWINGS

FIGS. 1 and 2 are exploded, isometric views of a cover mechanism in accordance with a preferred embodiment of the present invention, but viewed from different aspects;

FIGS. 3 and 5 are assembled views of FIG. 2, respectively schematically showing the cover mechanism in different working states; and

FIG. 4 is a cross sectional view of FIG. 3.

### DETAILED DESCRIPTION

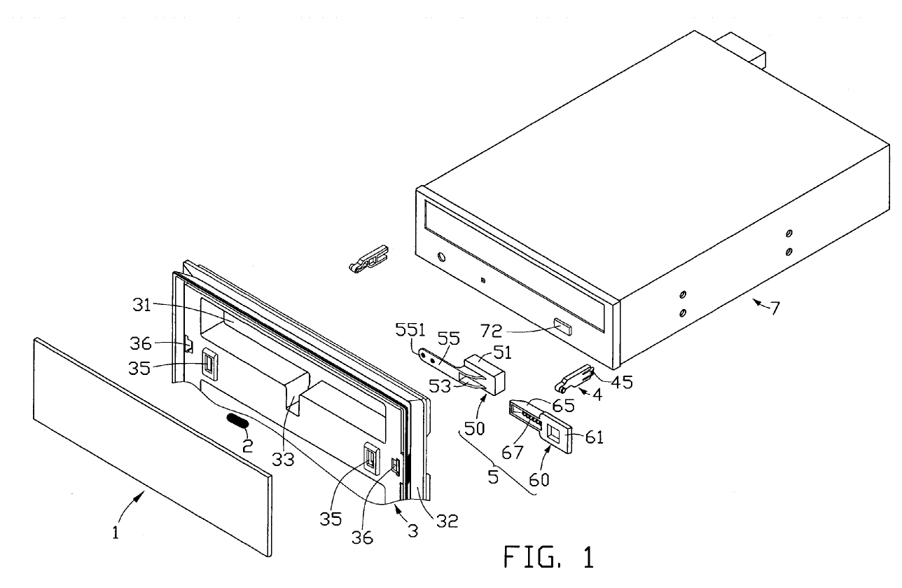

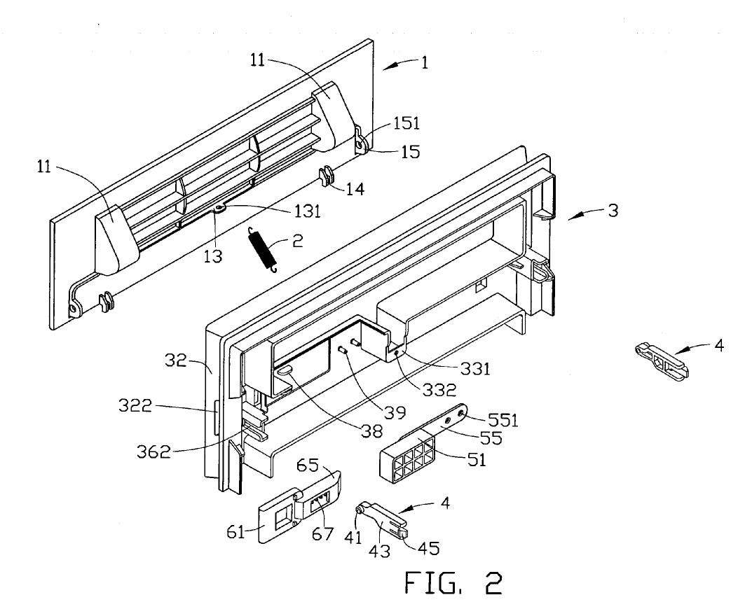

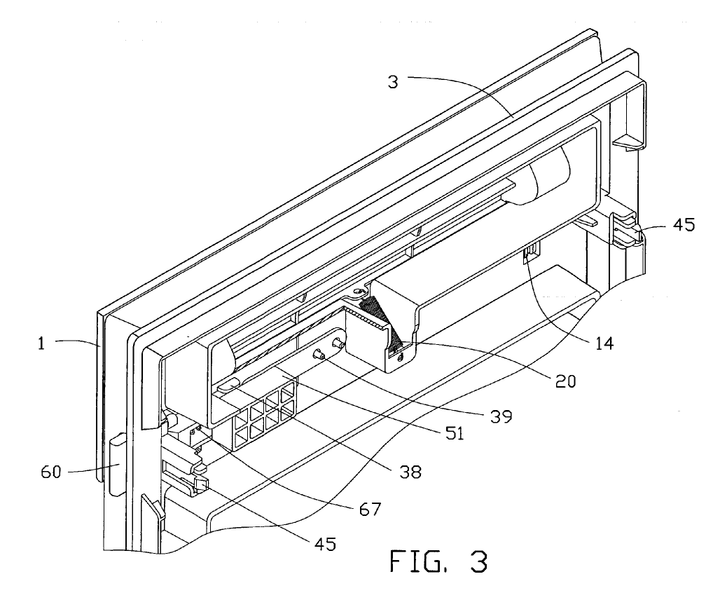

Referring to FIGS. 1 and 2, a cover mechanism of an electronic appliance in accordance with the preferred embodiment of the present invention is adapted for protecting a storage device 7 from accidental damage. In this preferred embodiment, the storage device 7 is an optical driver. The cover mechanism includes a bezel 3, a cover 1 attached to the bezel 1, a resilient member 2 disposed between the cover 1 and the bezel 3, and a pair of relay members 4 movably connecting the cover 3 to the bezel 3.

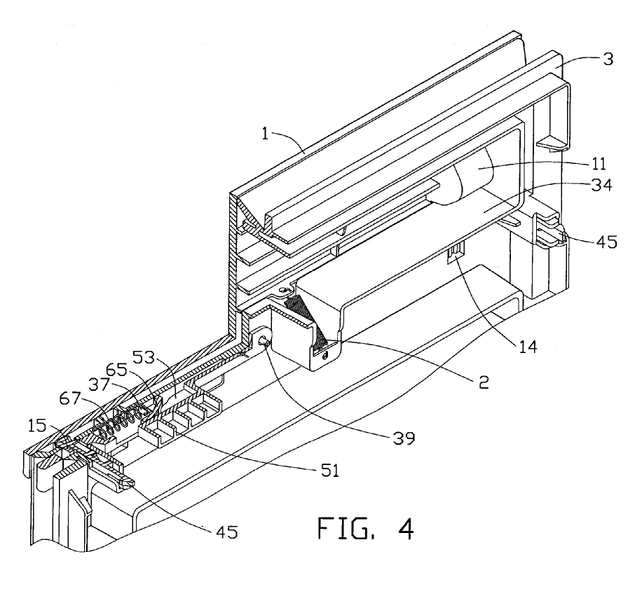

The bezel 3 includes an opening 31, a pair of passages 36, and a pair of notches 35 defined therein. The opening 31 is provided an entrance for the storage device 7 moving therethrough. A recess 33 is defined in the bezel 3 and connects to a lower portion of the opening 31. The notches 35 are respectively defined in the bezel 3 besides the recess 33. The passages 36 are defined in the bezel 3 besides the notches 35. A channel 362 is defined in an outer sidewall of each passage 36. A first fixing board 331 is formed at an inner edge of the recess 31. A first fixing aperture 332 is defined in the first fixing board 331. A pair of guiding tabs 38, and a pair of pins 39 extend perpendicularly from an inner side of the bezel 3. A slot 322 is defined in a side portion 32 of the bezel 3. Referring also to FIG. 4, a blocking bar 37 extends perpendicularly from an inner side of the bezel 1, corresponding to the slot 322.

The cover 1 includes a pair of triangular protrusions 11 extending from an inner side thereof. A second fixing board 13 perpendicularly extends from the cover 1 between the protrusions 11. A second fixing aperture 131 is defined in the second fixing board 13. A pair of connecting tabs 15 vertically extends from the cover 1 below the protrusions 11. A pivoting hole 151 is defined in each connecting tab 15. A pair of hooks 14 extrudes from a bottom portion of the cover 1.

Each relay member 4 includes a body 43, a shaft 41, and a catch 45. The bodis 43 slide in the passages 36 of the bezel 3. Each of the shafts 41 is formed at one end of the corresponding relay member 4 and pivotally received in the corresponding pivoting hole 151 of the cover 1. Each of the catches 45 is formed at another end of each relay member 4 and slides in each channel 362 of the passages 36 of the bezel 3.

The resilient member 2 is received in the recess 33 of the bezel 3 when the cover 1 covers the bezel 3. The resilient member 2 is a coil spring, with its two ends separately fixed in the first fixing hole 332 of the bezel 3 and the second fixing aperture 131 of the cover.

The optical disk drive 7 includes a switch 72 fixed in a front side thereof. A button assembly 5 is attached to the bezel 3 to actuate the switch 72. The button assembly 5 includes a button 60, a touch member 50, and a spring 67. The touch member 50 includes a sloping portion 53, touch portion 51, and a pair of through holes 551 defined in one end thereof. The button 60 is slidably attached to the bezel 3 via the slot 322 of the bezel 3. The button 60 includes a hollow wedge end 65 for receiving the spring 67 therein and abuts against the sloping portion 53 of the touch member 50 to trigger the switch 72. The spring 67 contacts the blocking bar 37 of the bezel 3.

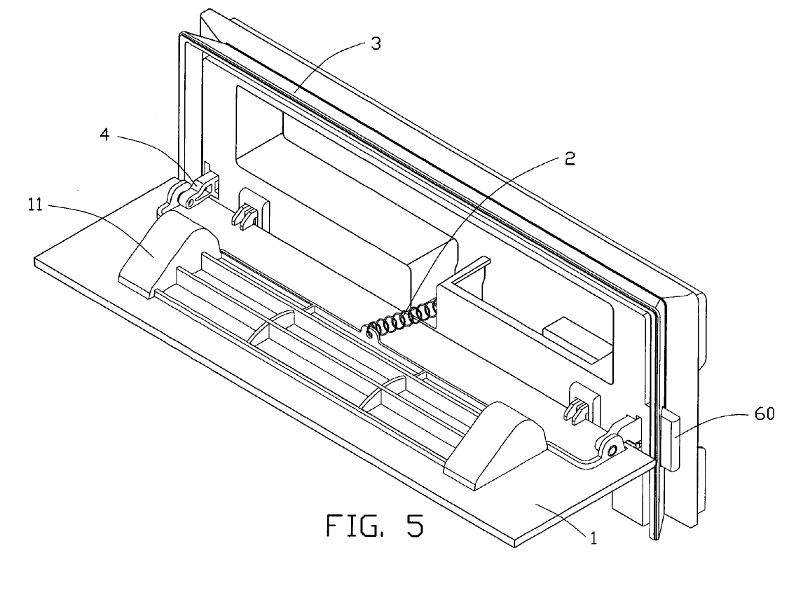

Referring also to FIGS. 4 to 6, in assembly, the cover 1 is attached to the bezel 3. The hooks 14 of the cover 1 movably engage in the notches 35 of the bezel 3. The relay members 4 are extended through the passages 36 of the bezel 3, with the shafts 41 received in the pivoting holes 151 of the cover 1 and the catches 45 sliding in the channels 362 of the bezel 3. Two ends of the resilient member 2 are separately fixed in the first fixing aperture 332 of the bezel 3 and the second fixing holes 131 of the cover 1. The protrusions 11 of the cover 1 are received in the opening 31 and contact the storage device 7.

The button 60 is inserted into the slot 322 of the bezel 3 and slides between the guiding tabs 38. The blocking bar 37 of the bezel 3 is received in the wedge end 65 of the button 60. The spring 67 is disposed in the wedge end 65 and contacts the blocking bar 37. The touch member 50 is attached to the bezel 3, with the pins 39 extending through the through holes 551. The wedge end 65 of the button 60 abuts the sloping portion 53 of the touch member 50.

To open the cover 1, the button 60 is pushed inwardly. The wedge end 65 abuts against the sloping portion 53 of the touch member 50 and the spring 67 is depressed. The touch portion 51 is moved to trigger the switch 72 of the storage device 7. The storage device 7 is moved out from the opening 31 of the bezel 3 and gradually urges the protrusions 11 to propel the cover 1 outwardly. The resilient member 2 is stretched. The bodies 43 of the relay members 4 are moved outwardly. Then the shafts 41 of the relay members 4 rotate in the pivoting holes 151 of the cover 1. The cover 1 is gradually opened and the storage device 7 can be operated. The spring 67 rebounds when the button 60 is released. The button assembly 5 accordingly moves back to its original position. The resilient member 2 rebounds and the cover 1 covers the bezel 3 again.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment.

What is claimed is:

1. A cover mechanism for protecting a storage device installed in an electronic device, the cover mechanism comprising:
a bezel defining an opening for the storage device passing therethrough, and a pair of passages;
a cover covering the opening of the bezel;
a pair of relay members each comprising a shaft rotatably attached to the cover, and a body slidably received in the passages of the bezel; and
a resilient member disposed between the cover and the bezel.

2. The cover mechanism as claimed in claim 1, wherein a channel is defined in a sidewall of each of the passages, the body of each of the relay members comprises a catch slidably engaging with the channel.

3. The cover mechanism as claimed in claim 1, wherein the bezel further comprises a pair of notches, the cover further comprises a pair of hooks engaging in the notches.

4. The cover mechanism as claimed in claim 1, wherein the cover comprises a pair of connecting tabs each defining a pivoting hole therein, the pivoting holes rotatably receive the shafts of the relay member therein.

5. The cover mechanism as claimed in claim 1, wherein the cover comprises a first fixing board with a first fixing aperture, the bezel comprises a second fixing board defining a second fixing aperture, the resilient member is a coil spring, two ends of the coil spring are fixed in the first and second fixing apertures.

6. The cover mechanism as claimed in claim 1, wherein the cover comprises a pair of protrusions movably received in the opening of the bezel, the protrusions have triangular configurations.

7. The cover mechanism as claimed in claim 1, wherein the bezel further comprises a slot defined in a side portion thereof, for extending a button assembly therethrough.

8. The cover mechanism as claimed in claim 7, wherein the button assembly comprises a button slidably attached to the bezel, and a touch member with one end fixed on the bezel.

9. The cover mechanism as claimed in claim 8, wherein the button comprises a wedge end, the touch member comprises a sloping end abutted against by the wedge end.

10. A combination comprising:
a storage device comprising a switch;
a bezel defining an opening for the storage device moving therethrough, and at least one passage;
a cover covering the opening;
at least one relay member slidably received in said passage and pivotally attached to the cover at one end thereof; and
a button assembly attached to the bezel, the button assembly actuating the switch to move the storage device.

11. The combination as claimed in claim 10, wherein the cover comprises at least one connecting tab defining a pivoting hole therein, said relay member comprises a shaft in an end portion thereof and rotatably received in the pivoting hole.

12. The combination as claimed in claim 10, wherein a channel is defined in a sidewall of said passage, said relay member comprises a body sliding in said passage, the body comprises a catch engaging in the channel.

13. The combination as claimed in claim 10, wherein the cover comprises a pair of protrusions movably received in the opening of the bezel and contact the storage device.

14. The combination as claimed in claim 10, wherein the bezel further comprises a pair of notches defined therein, the cover further comprises a pair of hooks engaging in the notches.

15. The combination as claimed in claim 10, further comprising a resilient member arranged between the bezel and the cover, wherein the resilient member is a coil spring, the cover comprises a first fixing board with a first fixing aperture, the bezel comprises a second fixing board defining a second fixing apertures, two ends of the coil spring are fixed in the first and second apertures.

16. The combination as claimed in claim 10, wherein the bezel further comprises a slot defined in a side portion thereof, for extending the button assembly therethrough.

17. The combination as claimed in claim 16, wherein the button assembly comprises a button slidably attached to the bezel, and a touch member with one end fixed on the bezel.

18. The combination as claimed in claim 17, wherein the button comprises a wedge end, the touch member comprises a sloping end abutted against by the wedge end.
